(19) United States
(12) Patent Application Publication
(10) Pub. No.: US 2016/0148669 A1
(43) Pub. Date: May 26, 2016

(54) CONVERSION BOARD AND MOTHERBOARD HAVING SAME

(71) Applicants: HONG FU JIN PRECISION INDUSTRY (WuHan) CO., LTD., Wuhan (CN); HON HAI PRECISION INDUSTRY CO., LTD, New Taipei (TW)

(72) Inventors: YONG-ZHAO HUANG, Wuhan (CN); YI-HUNG PENG, New Taipei (TW)

(21) Appl. No.: 14/590,163

(22) Filed: Jan. 6, 2015

(30) Foreign Application Priority Data
Nov. 21, 2014 (CN) 201410671769.6

(51) Int. Cl. G11C 11/4074; H05K 1/18; H05K 1/14

(52) U.S. Cl. CPC G11C 11/4074; H05K 1/141; H05K 1/18; H05K 2201/10363; H05K 2201/10189; H05K 2201/10022; H05K 2201/10015

(57) ABSTRACT

A motherboard includes a first memory, a power supply, a jumper, a second memory slot and a conversion board. A first idle pin of the second memory slot is coupled to the power supply through the jumper. The motherboard supplies power to the first memory and ensures communication with the first memory by virtue of the conversion board. A conversion board is also provided.

### FIELD

The subject matter herein generally relates to a conversion board and a motherboard having the conversion board.

### BACKGROUND

A double data rate synchronous dynamic random access memory III (DDR3) cannot be driven by a double data rate synchronous dynamic random access memory IIII (DDR4) slot.

### BRIEF DESCRIPTION OF THE DRAWINGS

Implementations of the present technology will now be described, by way of example only, with reference to the attached figures.

FIG. 1 is a block diagram of an embodiment of a motherboard.

FIG. 2 is a circuit diagram of an embodiment of a conversion board of the motherboard.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like.

The present disclosure is described in relation to a motherboard 100.

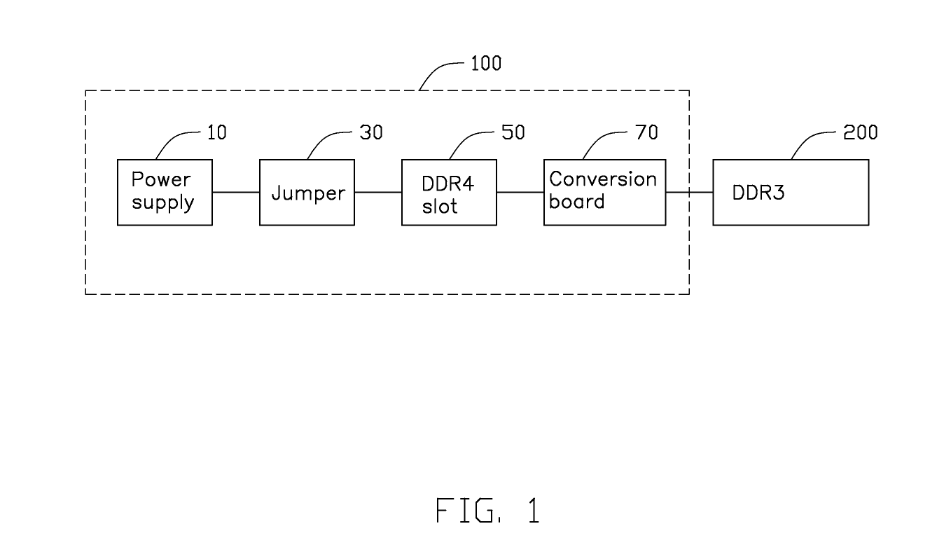

FIG. 1 illustrates an embodiment of the motherboard 100. The motherboard 100 is capable of coupling with a DDR4 (not shown) or a DDR3 200, and can comprise a power supply 10, a jumper 30, a DDR4 slot 50, and a conversion board 70. A DDR3 200 is capable of coupling to the conversion board 70. In at least one embodiment, the power supply 10 can supply 3 volts.

The DDR4 can be inserted in the DDR4 slot 50. A plurality of terminals disposed in the DDR4 slot 50 corresponds to a plurality of pins of the DDR4. A first idle terminal of the DDR4 slot 50 is coupled to the power supply 10 through the jumper 30.

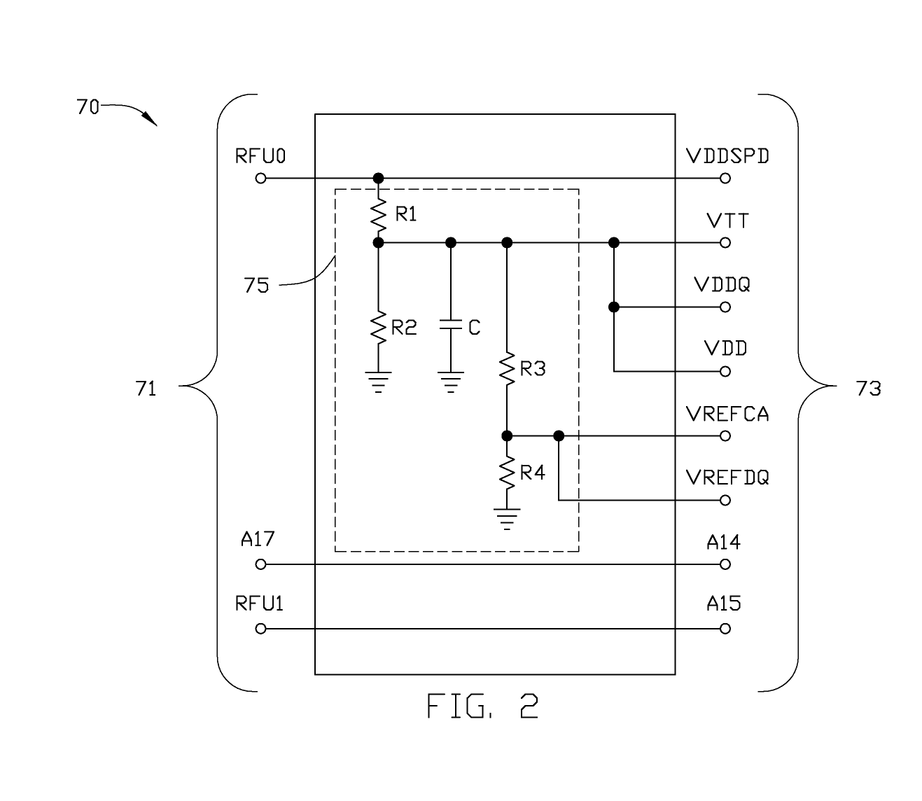

FIG. 2 illustrates an embodiment of the conversion board 70. In at least one embodiment, the conversion board 70 is a printed circuit board (PCB). The conversion board 70 can comprise a first interface 71, a second interface 73, and a conversion circuit 75. A plurality of pins, corresponding to the terminals of the DDR4 slot 50 is disposed in the first interface 71. The pins of the first interface 71 follow pins specification of the DDR4. There is a one-to-one correspondence between the pins of the first interface 71 and the terminals of the DDR4 slot 50 when the first interface 71 is inserted in the DDR4 slot 50. A first idle pin RFUO of the first interface 71 is coupled to the first idle terminal of the DDR4 slot 50. In at least one embodiment, the power supply 10 outputs 3 volts.

A plurality of terminals, corresponding to a plurality of pins of the DDR3, is disposed in the second interface 73. The terminals of the second interface 73 follow terminals specification of a DDR3 slot for inserting the DDR3 200. A first power terminal VDDSPD of the second interface 73 is coupled to the first idle pin RFUO of the first interface 71. The 3 volts from the first power terminal VDDSPD of the second interface 73 is converted to 1.5 volts by the conversion circuit 75, and then the 1.5 volts is output to second power terminals VTT, VDDQ, VDD of the second interface 73. The 3 volts from the first power terminal VDDSPD of the second interface 73 is also converted to 0.75 volts by the conversion circuit 75, and then the 0.75 volts is outputted to third power terminals VREFCA, VREFDQ of the second interface 73. A fourteenth signal terminal A14 of the second interface 73 is coupled to a seventeenth signal pin All of the first interface 71. A fifteenth signal terminal A15 of the second interface 73 is coupled to a second idle pin RFUl of the first interface 71. There is a one-to-one correspondence between the other pins of the first interface 71 and other terminals of the second interface 73.

The conversion circuit 75 can comprise resistors R1-R4 and a capacitor C. The first power terminal VDDSPD of the second interface 73 is coupled to the second power terminals VTT, VDDQ, VDD of the second interface 73 through the resistor R1. The second power terminals VTT, VDDQ, VDD of the second interface 73 are coupled to ground through the resistor R2. The second power terminals VTT, VDDQ, VDD of the second interface 73 are also coupled to ground through the capacitor C. The third power terminals VREFCA, VREFDQ of the second interface 73 are coupled to the second power terminals VTT, VDDQ, VDD of the second interface 73 through the resistor R3. The third power terminals VREFCA, VREFDQ of the second interface 73 are also coupled to ground through the resistor R4.

When using the DDR3 200, the jumper 30 is coupled to the motherboard 100 and the DDR3 200 is coupled to the second interface 73, the power supply 10 is coupled to the DDR4 slot 50. An input voltage of 3 volts is received by the first power terminal VDDSPD from the power supply 10. The conversion circuit 75 converts the input voltage to 1.5 volts and 0.75 vols. The 1.5 volts is output to second power terminals VTT, VDDQ, VDD. The 0.75 volts is output to third power terminals VREFCA, VREFDQ of the second interface 73. The DDR3 200 can be driven.

When to use the DDR4, the jumper 30 is detached from the motherboard 100, and the DDR4 is inserted in the DDR4 slot 50.

In at least one embodiment, the DDR4 slot 50 is closest to a memory controller on the motherboard 100 for protection the communication quality.

The embodiments shown and described above are only examples. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A motherboard capable of coupling with a first memory and a second memory, the motherboard comprising:
a power supply;
a first memory slot capable of coupling with the first memory; and
a conversion board comprising:
a first interface configured to couple with the first memory slot and comprising a first idle pin, a second idle pin, and a signal pin; and
a second interface configured to couple with the second memory and comprising a first power terminal coupled to the first idle pin of the first interface, a plurality second power terminals, a plurality of third power terminals, a first signal terminal coupled to the signal pin, and a second signal terminal coupled to the second idle pin; and
a conversion circuit coupled between the first interface and the second interface;
wherein to couple the second memory to the motherboard, a jumper is coupled to the motherboard, the first power terminal receives an input voltage from the power supply, the conversion circuit converts the input voltage to a first voltage and a second voltage, the first voltage is output to the second power terminals, and the second voltage is output to the third power terminals; and
to couple the first memory to motherboard, the jumper is detached from the motherboard and the first memory is coupled in the first memory slot.

2. The motherboard of claim 1, wherein the first memory slot comprises an idle end, when the jumper is coupled to the motherboard, the idle end couples the power supply to the first memory slot.

3. The motherboard of claim 1, wherein the power supply supplies 3 volts.

4. The motherboard of claim 1, wherein the first memory is a double data rate synchronous dynamic random access memory IIII (DDR4), the first memory slot is a DDR4 slot, the second memory is a double data rate synchronous dynamic random access memory III (DDR3).

5. The motherboard of claim 1, wherein the first memory slot is closest with a memory controller on the motherboard.

6. The motherboard of claim 1, wherein the conversion circuit comprises first to fourth resistors, and a capacitor, the first power terminal is coupled to the second power terminals through the first resistor, the second power terminals are grounded through the second resistor, the second power terminals are also grounded through the capacitor, the third power terminals are coupled to the second power terminals through the third resistor, and the third power terminals are also grounded through the fourth resistor.

7. The motherboard of claim 1, wherein the conversion board is a printed circuit board (PCB).

8. A conversion board comprising:
a first interface configured to couple with a first memory slot and comprising a first idle pin, a second idle pin, and a signal pin;
a second interface configured to couple with a second memory and comprising a first power terminal coupled to the first idle pin of the first interface, a plurality second power terminals, a plurality of third power terminals, a first signal terminal coupled to the signal pin, and a second signal terminal coupled to the second idle pin; and
a conversion circuit coupled between the first interface and the second interface;
wherein the first power terminal receives an input voltage from the power supply, the conversion circuit converts the input voltage to a first voltage and a second voltage, the first voltage is output to the second power terminals, the second voltage is output to the third power terminals.

9. The conversion board of claim 8, wherein the first memory slot is a double data rate synchronous dynamic random access memory IIII (DDR4) slot, the second memory is a double data rate synchronous dynamic random access memory III (DDR3).

10. The conversion board of claim 8, wherein the conversion circuit comprises first to fourth resistors, and a capacitor, the first power terminal is coupled to the second power terminals through the first resistor, the second power terminals are grounded through the second resistor, the second power terminals are also grounded through the capacitor, the third power terminals are coupled to the second power terminals through the third resistor, and the third power terminals are also grounded through the fourth resistor.

11. The conversion board of claim 8, wherein the conversion board is a printed circuit board (PCB).
